(19) United States
(12) Patent Application Publication
(10) Pub. No.: US 2006/0225642 A1
(43) Pub. Date: Oct. 12, 2006

(54) Method of forming semiconductor crystal

(76) Inventors: Yoshihiko Kanzawa, Yawata-shi (JP); Tohru Saitoh, Osaka (JP); Akira Asai, Osaka (JP); Teruhito Ohnishi, Osaka (JP)

Correspondence Address: MCDERMOTT, WILL & EMERY;Michael E. Fogarty, 600 13th Street, N.W., Washington, DC, 20005-3096, US

(21) Appl. No.: 10/402,239

(22) Filed: Mar. 31, 2003

(51) Int. Cl. C30B 23/00; C30B 25/00; C30B 28/12; C30B 28/14

(52) U.S. Cl. 117/89

(57) ABSTRACT

A method of forming semiconductor crystal of the present invention comprises the steps of heating a Si substrate to clean a surface of the Si substrate, epitaxially growing Si crystal on the Si substrate inside a crystal growth chamber at a growth temperature lower than a substrate temperature of the Si substrate in the cleaning step and higher than a growth temperature at which SiGe crystal is epitaxially grown later, and epitaxially growing the SiGe crystal on the Si crystal.

### BACKGROUND OF THE INVENTION

1. Field of the Invention

The present invention relates a method of forming semiconductor crystal, and more particularly to a method of forming semiconductor crystal by epitaxially growing crystal different from Si, on a Si (silicon) substrate.

2. Description of the Related Art

In recent years, attention has been focused on a mixed crystal semiconductor (SiGe) comprising Si and Ge (germanium) or a mixed semiconductor (SiGeC) comprising Si, Ge, and C (carbon), as materials of ultra-high speed semiconductor devices using Si based materials. Commonly, these mixed crystal semiconductors are applied to devices in such a manner that crystal different from Si is epitaxially grown on the Si substrate to form a hetero structure with Si.

In such epitaxial growth, if contaminations adhere onto the Si substrate, such contaminations become a seed and crystal defects occur in the epitaxially grown layer. In worst case, the defects occur in the Si substrate side in addition to the epitaxially grown layer. Since such defects adversely affect device performance, it is necessary to remove the contaminations from a surface of the Si substrate to make the surface as clean as possible and then grow the crystal, prior to the epitaxial growth.

Commonly, the substrate surface is cleaned by two methods, i.e., substrate cleaning using chemical solutions and thermal cleaning in which the substrate is heated to be cleaned just before the crystal growth. The cleaning using the chemical solutions is performed in such a manner that the substrate is immersed in a mixed solution containing sulfuric acid and hydrogen peroxide solution or a mixed solution containing ammonia and hydrogen peroxide solution. The substrate cleaning by the thermal cleaning is performed in such a manner that the substrate is introduced into a crystal growth apparatus in a ultra-high vacuum or hydrogen atmosphere and is heated at a high temperature of approximately 800° C. to allow the contaminations on the substrate surface to be evaporated.

Needless to say, degree of cleanliness of the substrate surface is highest just after the thermal cleaning. After the thermal cleaning is finished, the substrate surface is gradually contaminated by air or the like remaining inside the crystal growth apparatus even when the substrate is held in the ultra-high vacuum atmosphere. For this reason, it is desirable to grow desired crystal on the substrate just after the thermal cleaning.

However, in a step of actual crystal growth, it is sometimes difficult to perform crystal growth just after thermal cleaning. This is because a step of cooling the substrate or a step of moving the substrate to a predetermined position becomes necessary. These steps will be described below in detail.

As described above, the step of thermal cleaning is performed at a temperature of approximately of 800° C. On the other hand, in the case of SiGe or SiGeC, if the epitaxial growth is performed on Si at a high temperature of approximately 800° C., defects occur, and therefore the epitaxial growth is performed at a low temperature of approximately 500 to 600° C. In this case, the temperature needs to be reduced from “800° C.” at which the thermal cleaning is performed, to “500 to 600° C.” at which the crystal growth is performed.

In general, it takes a certain time to stabilize the temperature after the temperature is reduced as described above in any crystal growth apparatus. As a matter of course, during this time, the cleaned substrate surface is contaminated to some degrees. In general, in a system for heating the substrate using an infrared lamp, such time is favorably short. On the other hand, in a system for heating the substrate using a heater, time longer than 10 minutes is sometimes necessary depending on experimental conditions.

In addition to the above-mentioned time required for reducing the temperature, it takes a certain time to move the substrate to a predetermined position after the thermal cleaning, depending on a configuration of crystal growth apparatus. For example, the thermal cleaning is performed inside a first vacuum chamber and actual crystal growth is performed inside a second vacuum chamber. In this case, the substrate is exposed in vacuum or hydrogen atmosphere for the time during which the substrate is moved from the first vacuum chamber to the second vacuum chamber. Therefore, during this time, the cleaned surface is contaminated.

A description will be given of experimental result of how the substrate surface is actually contaminated when it is left after the thermal cleaning. In this experiment, the substrate is cleaned using chemical solutions and then introduced into a crystal growth apparatus for thermal cleaning. The substrate is left in vacuum for a certain time and then SiGe crystal is epitaxially grown on the substrate. How quality of the SiGe crystal changes depending on time during which the crystal is left in vacuum is examined.

An actual detailed experimental procedure is as follows. First, a Si substrate is cleaned using a mixed solution containing sulfuric acid and hydrogen peroxide solution, thereby removing organic substances and metal contamination substances on the substrate surface. Then, the Si substrate is cleaned using an aqueous solution containing ammonia and hydrogen peroxide, thereby removing small particles adhering to the Si substrate. Further, using a hydrofluoric acid solution, a native oxide film is removed from the surface of the Si substrate. Finally, the Si substrate is re-immersed in the aqueous solution containing ammonia and hydrogen peroxide, thereby forming a thin protection oxide film on the surface of the Si substrate.

The Si substrate that has gone through the above pretreatment is introduced into the crystal growth apparatus. As the crystal growth apparatus, an ultra-high vacuum chemical vapor deposition apparatus (UHV-CVD apparatus) that is configured to heat the substrate by an infrared lamp is used. After the Si substrate is introduced into a crystal growth chamber, the chamber is evacuated to 266.644×10⁻⁹ Pa (2×10⁻⁹ Torr, 1 Torr=133.322 Pa). Then, the Si substrate is heated up to a temperature of 850° C. in a hydrogen gas atmosphere to cause the protection oxide film formed on the Si substrate to be removed by sublimation, thereby exposing the cleaned surface of the Si substrate.

Then, the temperature of the Si substrate is reduced to 500° C. and left in vacuum for a certain time. Then, source gases are introduced into the apparatus and crystal growth is performed. Si₂H₆ gas and GeH₄ gas, as the source gases, are introduced into the apparatus so that the pressure of the Si₂H₆ gas and the pressure of the GeH₄ gas are adjusted to be 933.254×10⁻⁵ Pa and 333.305×10⁻⁴ Pa, respectively, inside the apparatus. The crystal growth is performed for 10 minutes. Under the condition, crystal grows to be 130 nm at a Ge concentration of 26% on the Si substrate.

X-ray diffraction (XRD) spectrums of samples so created are shown in FIG. 1. In FIG. 1, results of crystal growth in the case where the substrate is left in vacuum for 30 seconds, 600 seconds, and 900 seconds after the thermal cleaning, in this order from below. As shown in FIG. 1, in all spectrums, sharp peaks appearing at a location of “0 sec” are peaks caused by diffraction of (004) planes of Si used as the substrate. Peaks of the grown SiGe crystal appear in the vicinity of 2200 sec. Periodic fine peaks appear around main peaks in the vicinity of 2200 sec. These peaks reflect degrees of flatness and crystallinity of the crystal and are called fringes. In general, the more clear the fringe are, the higher degrees of flatness and crystallinity of the deposited crystal are. In the XRD spectrum of the crystal in the case where the substrate is left for 30 seconds, its fringes are very clear and fringe peaks have very deep cuts. This follows that the SiGe crystal has an extremely high degree of flatness. In the XRD spectrum of the crystal in the case where the substrate is left in vacuum for 600 seconds, its cuts are shallower than those of the spectrum for 30 seconds, but clear fringes appear. This follows that the SiGe crystal has relatively high degrees of flatness and crystallinity. On the other hand, in the case where the substrate is left in vacuum for 900 seconds, fringes almost vanish, and the degrees of flatness and crystallinity of the SiGe crystal are reduced. This might be due to the fact that the substrate surface is contaminated after the thermal cleaning and defects occur therefrom as a seed.

As should be appreciated from the foregoing, when the substrate is cleaned using chemical solutions and the surface of the substrate cleaned by the thermal cleaning is exposed but thereafter the substrate is left, the surface is contaminated and quality of the deposited SiGe crystal is degraded.

As a solution to this, conventionally, there has been used a method, in which a Si layer called a buffer layer is deposited on the substrate prior to epitaxial growth of crystal different from Si, such as SiGe, for the purpose of improving quality of the deposited crystal such as SiGe, formed on the Si buffer layer.

FIG. 2 is a view showing XRD spectrums of samples in the case where how quality of crystal changes depending on the condition with and without the Si buffer layer. The samples are created in the same manner as described above. That is, after the substrate cleaning is performed using chemical solutions and thermal cleaning is performed in the crystal growth apparatus, the substrate is left in vacuum for 900 seconds and thereafter, the SiGe is epitaxially grown. The sample of the spectrum shown on the lower side in FIG. 2 (represented by “no Si buffer”) is created by directly growing SiGe on the Si substrate, while the sample of the spectrum shown on the upper side in FIG. 2 (represented by “Si buffer”) is created by depositing the Si buffer layer to be 20 nm on the Si substrate and then by growing the SiGe layer on the Si substrate. As can be seen from FIG. 2, when the Si buffer layer is deposited, clear fringes appear. As should be understood, because of the presence of the Si buffer layer, the degrees of crystallinity and flatness of the SiGe layer are significantly improved. This is due to the fact that contaminations adhering to the substrate surface are well embedded in the Si buffer layer. On the other hand, in the absence of the Si buffer layer, SiGe crystal is deposited as having large distortion on the substrate surface contaminated by the adhering contaminations, thereby causing defects and break up of the crystal.

As should be appreciated from the foregoing, there has been conventionally used a method in which, when the SiGe is deposited on the Si substrate, the Si buffer layer having a film thickness of several tens nm or more is deposited and then SiGe or SiGeC crystal is deposited.

In recent years, with development of precise device structures, it is sometimes undesirable that even the buffer layer having a thickness of approximately several tens nm be deposited. One example of this is a case where selective epitaxial growth is used in fabrication of devices. In general, when the Si substrate patterned with SiO₂, a nitride film or the like, is irradiated with the Si₂H₆ gas or the GeH₄ gas, the gas is decomposed only on the exposed Si crystal and is not decomposed on the SiO₂, the nitride film or the like, for a certain time. Using this characteristic, crystal is selectively grown only on the exposed Si crystal. But, after an elapse of the certain time, the gas is also decomposed on the SiO₂, the nitride film, or the like, and polycrystal is deposited. This will be described with reference to FIG. 3.

FIG. 3 is a cross-sectional view for explaining how the conventional selective epitaxial growth occurs. As shown in FIG. 3, on a Si substrate 101, a Si buffer layer 102 is formed to have a film thickness of approximately several tens nm on the Si substrate 101. To perform selective epitaxial growth, the Si substrate 101 is patterned with a SiO₂ film 104. In this case, when the Si substrate 101 is introduced into the crystal growth apparatus and is irradiated with the Si₂H₆ gas or the GeH₄ gas, the gas is decomposed only on the Si buffer layer 102 for a certain time. But, after an elapse of the certain time, the gas is also decomposed on the SiO₂ film 104. As a result, polycrystal 105 such as poly Si or poly SiGe is deposited on the SiO₂ film 104.

It should appreciated from the above that, when such selective epitaxial growth is used in fabrication of devices, it is desirable to minimize the time during which the Si substrate is irradiated with the gas. It is therefore preferable that the Si buffer layer is not grown on the Si substrate, because the time during which the Si substrate is irradiated with the gas is made shorter. Nevertheless, when the Si buffer layer is grown, it is desirable to minimize the film thickness because the time is also made shorter.

However, as described above, commonly, in the absence of the Si buffer layer, the crystal deposited on the Si substrate is degraded.

### SUMMARY OF THE INVENTION

The present invention has been made under the circumstances, and an object of the present invention is to provide a method of forming semiconductor crystal, in which semiconductor crystal with high quality is formed without forming a Si layer on a Si substrate or by forming the Si layer having a relatively small film thickness thereon.

To achieve the above object, according to the present invention, there is provided a method of forming semiconductor crystal, comprising: a first step of heating a Si substrate to clean a surface of the Si substrate; a second step of epitaxially growing first semiconductor crystal containing at least Si on the Si substrate; and a third step of epitaxially growing second semiconductor crystal on the first semiconductor crystal, wherein the second semiconductor crystal comprises a material different from Si, and a growth temperature of the first semiconductor crystal in the second step is lower than a substrate temperature of the Si substrate in the first step and is higher than a growth temperature of the second semiconductor crystal in the third step.

Preferably, in the method of forming semiconductor crystal of the present invention, a film thickness of the first semiconductor crystal is not less than one monolayer and not more than 1 nm.

Preferably, in the method of forming semiconductor crystal of the present invention, the first semiconductor crystal is Si.

Preferably, in the method of forming semiconductor crystal of the present invention, the second semiconductor crystal contains Si and Ge.

Preferably, in the method of forming semiconductor crystal of the present invention, the second semiconductor crystal further contains C.

Preferably, in the method of forming semiconductor crystal of the present invention, the second semiconductor crystal contains Si and C.

Preferably, in the method of forming semiconductor crystal of the present invention, the first semiconductor crystal contains Ge, and both the second semiconductor crystal and the first semiconductor crystal are made of an identical material.

Preferably, in the method of forming semiconductor crystal of the present invention, the first semiconductor crystal further contains C.

Preferably, in the method of forming semiconductor crystal of the present invention, the first semiconductor crystal contains C, and both the second semiconductor crystal and the first semiconductor crystal are made of an identical material.

According to the present invention, there is further provided a method of forming semiconductor crystal, comprising: a first step of heating a Si substrate to clean a surface of the Si substrate; a second step of epitaxially growing first semiconductor crystal containing at least Si on the Si substrate; and a third step of epitaxially growing second semiconductor crystal on the first semiconductor crystal, wherein the second semiconductor crystal comprises a material different from Si, and when time that lapses from when the first step is completed until the first semiconductor crystal is epitaxially grown in the second step is represented by T (second) and a pressure inside a crystal growth chamber during epitaxial growth of the first semiconductor crystal is represented by P (Pa), T×P≦399.966×10⁻⁶ is satisfied.

Preferably, in the method of forming semiconductor crystal of the present invention, a film thickness of the first semiconductor crystal is not less than one monolayer and not more than 1 nm.

Preferably, in the method of forming semiconductor crystal of the present invention, the first semiconductor crystal is Si.

Preferably, in the method of forming semiconductor crystal of the present invention, the second semiconductor crystal contains Si and Ge.

Preferably, in the method of forming semiconductor crystal of the present invention, the second semiconductor crystal further contains C.

Preferably, in the method of forming semiconductor crystal of the present invention, the second semiconductor crystal contains Si and C.

Preferably, in the method of forming semiconductor crystal of the present invention, the first semiconductor crystal contains Ge, and both the second semiconductor crystal and the first semiconductor crystal are made of an identical material.

Preferably, in the method of forming semiconductor crystal of the present invention, the first semiconductor crystal further contains C.

Preferably, in the method of forming semiconductor crystal of the present invention, the first semiconductor contains C, and both the second semiconductor crystal and the first semiconductor crystal are made of an identical material.

The above and further objects and features of the invention will more fully be apparent from the following detailed description with accompanying drawings.

### BRIEF DESCRIPTION OF THE DRAWINGS

FIG. 1 is a view showing XRD spectrums (dependence on time during which a substrate is left in vacuum) of SiGe crystal formed by the conventional forming method;

FIG. 2 is view showing XRD spectrums (in the presence or absence of Si buffer) of the SiGe crystal formed by the conventional forming method;

FIG. 3 is a cross-sectional view for explaining how the conventional selective epitaxial growth occurs;

FIGS. 4(a) to 4(e) are views for explaining steps of a forming method according to a first embodiment of the present invention and cross-sectional views of products formed in the steps;

FIG. 5 is a view showing a XRD spectrum of SiGe crystal formed by the forming method according to the first embodiment;

FIG. 6 is a cross-sectional view for explaining how selective epitaxial growth occurs in the case of using the forming method of the present invention;

FIG. 7 is a plan view schematically showing a configuration of a crystal growth apparatus having a plurality of chambers;

FIGS. 8(a) to 8(e) are views for explaining steps of a method of forming semiconductor crystal according to a second embodiment of the present invention and cross-sectional views of products formed in the steps;

FIG. 9 is a view showing a XRD spectrum of SiGe crystal formed by the forming method according to the second embodiment of the present invention; and

FIG. 10 is a view for explaining steps of fabricating a semiconductor device.

### DETAILED DESCRIPTION OF PREFERRED EMBODIMENTS

Hereinafter, embodiments of the present invention will be described with reference to the drawings.

### Embodiment 1

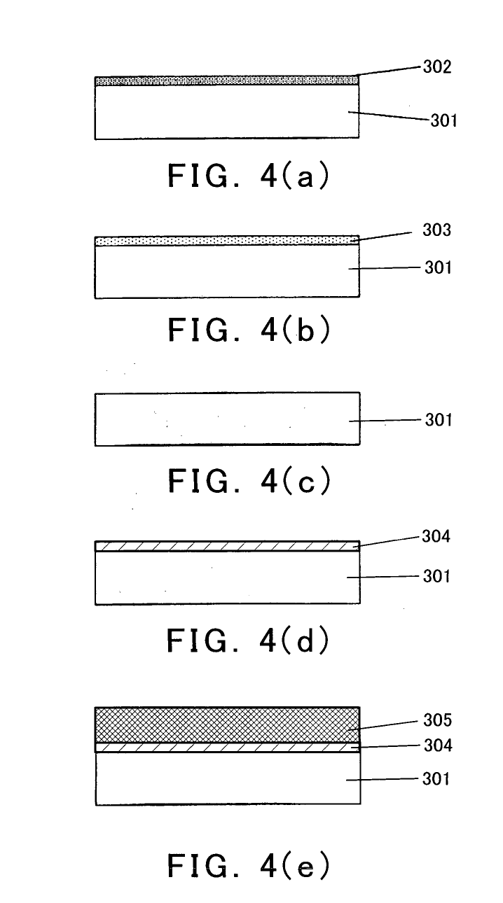

In a first embodiment, with reference to FIG. 4, a description will be given of a method of forming satisfactory semiconductor crystal on a Si substrate left for a long time by depositing a Si layer having a relatively small film thickness on the Si substrate.

FIGS. 4(a) to 4(e) are views for explaining steps of a forming method according to a first embodiment of the present invention and cross-sectional views of products formed in the steps. As shown in FIG. 4(a), on a Si substrate 301, a native oxide film 302 exists. The Si substrate 301 provided with the native oxide film 302 on a surface thereof is cleaned using a mixed solution containing sulfuric acid and hydrogen peroxide solution, thereby removing organic substances and metal contamination substances on the surface of the Si substrate 301. Then, the Si substrate 301 is cleaned using an aqueous solution containing ammonia and hydrogen peroxide, thereby removing small particles adhering to the Si substrate 301. Further, using a hydrofluoric acid solution, the native film oxide 302 on the surface of the Si substrate 301 is removed away. The Si substrate 301 is re-immersed in the aqueous solution containing ammonia and hydrogen peroxide, thereby forming a thin protection oxide film 303 on the surface of the Si substrate 301, as shown in FIG. 4(b).

The Si substrate 301 that has gone through the above pretreatment is introduced into a crystal growth apparatus. In this embodiment, an example using an ultra-high vacuum chemical vapor deposition process (UHV-CVD process) as a crystal growth method, will be described. This method is a forming method of semiconductor crystal characterized in that crystal growth is performed under an ultra-high vacuum back pressure of 133.322×10⁻⁸ Pa or less. A UHV-CVD apparatus used herein is configured to heat the substrate using an infrared lamp. In this embodiment, first, the Si substrate 301 is introduced into the crystal growth chamber, which is then evacuated to 266.644×10⁻⁹ Pa. Then, the Si substrate 301 is heated up to a temperature of 850° C. in a hydrogen gas atmosphere to cause the protection oxide film 303 formed on the Si substrate 301 to be removed by sublimation and contaminations on the surface of the Si substrate 301 to be removed away, thereby exposing a clean surface of the Si substrate 301, as shown in FIG. 4(c).

Then, the temperature of the Si substrate 301 is reduced for 30 seconds to 600° C. and temporarily kept at 600° C. Then, a Si₂H₆ gas is fed into the crystal growth chamber so that the pressure of the Si₂H₆ gas is 933.254×10⁻⁵ Pa inside the crystal growth chamber, thereby causing a Si crystal layer 304 (layer comprising first semiconductor crystal) to be epitaxially grown on the Si substrate 301, as shown in FIG. 4(d). The growth time is set to 5 seconds. Thereby, the Si crystal layer 304 is grown to be approximately 0.5 nm. Then, the substrate temperature is reduced to 500° C. which is the growth temperature of the SiGe crystal, in which state, the substrate 301 is left for 15 minutes (900 seconds). Thereafter, as shown in FIG. 4(e), a SiGe crystal layer 305 (layer comprising second semiconductor crystal) is deposited on the Si crystal layer 303. At this time, the Si₂H₆ gas and the GeH₄ gas are fed into the crystal growth chamber so that the pressure of the Si₂H₆ gas and the pressure of the GeH₄ gas are 933.254×10⁻⁵ Pa and 333.305×10⁻⁴ Pa, respectively. The growth time is set to 600 seconds. Under the condition, the SiGe layer 305 is grown to be 130 nm at a Ge concentration of 26% on the Si crystal layer 304.

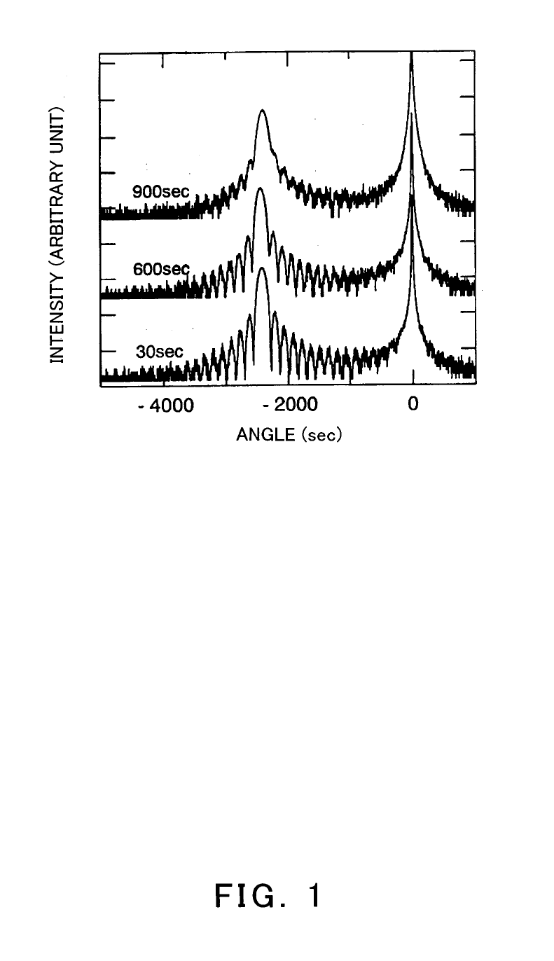

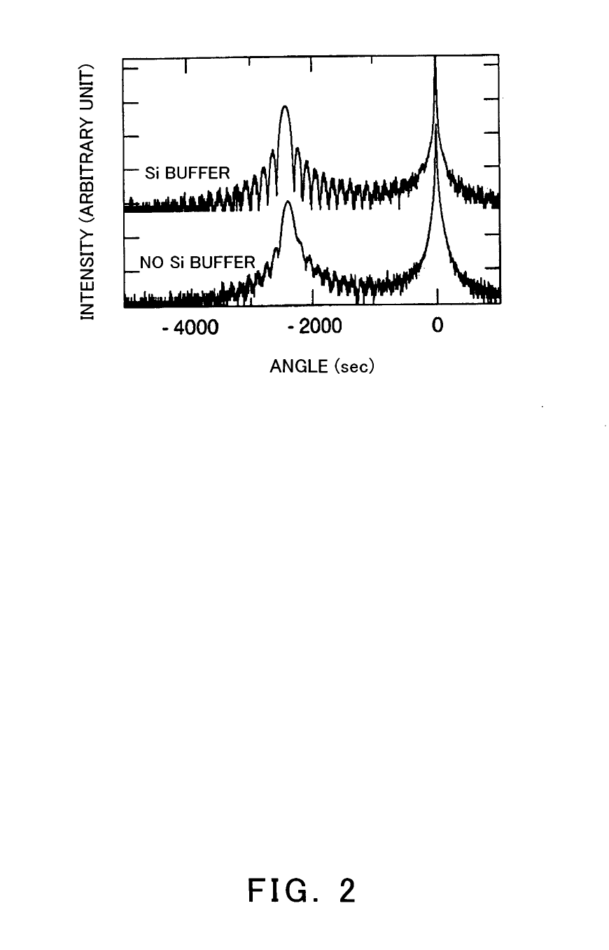

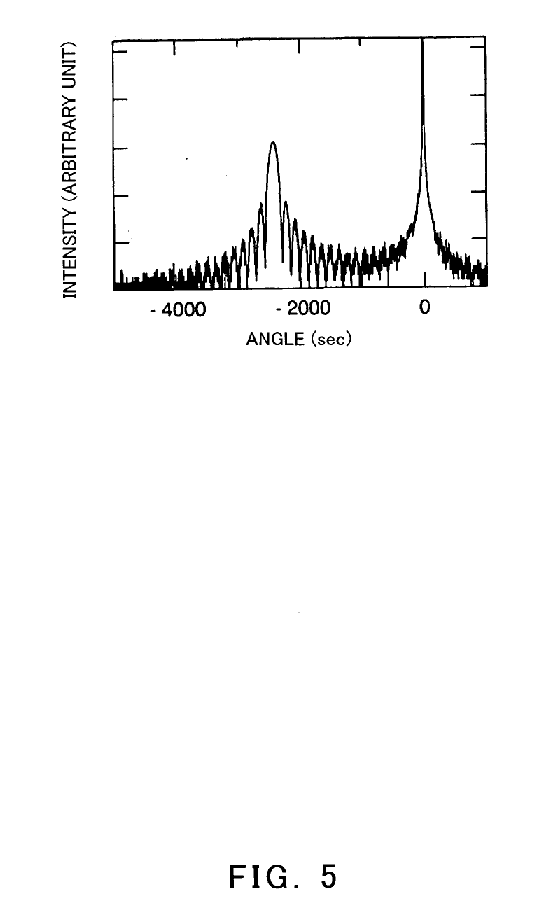

FIG. 5 shows a XRD spectrum of the SiGe layer 305 formed as described above. In FIG. 5, as in the case of FIGS. 1 and 2, a sharp peak appearing at a location of “0 sec” is a peak due to diffraction of (004) planes of Si used as the substrate and a peak appearing in the vicinity of 2200 sec is a peak due to diffraction of the SiGe crystal layer 305. Periodic fine peaks appearing around the main peak in the vicinity of 2200 sec are fringes showing degrees of flatness and crystallinity of the SiGe crystal layer 305. With reference to FIG. 5, the fringes are very clear, which shows that degrees of the crystallinity and flatness of the deposited SiGe crystal layer 305 are very high.

As can be seen from the spectrum shown on the uppermost side in FIG. 1, after the thermal cleaning, if the Si substrate is left for 900 seconds and then the SiGe crystal layer is deposited on the Si substrate, it is observed that the XRD spectrum has obscure fringes. This follows that the degrees of crystallinity and flatness of the SiGe crystal layer are degraded. However, as in this embodiment, when the Si crystal layer 304 having a relatively small fim thickness of approximately 0.5 nm is deposited on the Si substrate 301 in a relatively short time after the thermal cleaning, and then the Si substrate 301 is left in vacuum for 900 seconds, degradation of degrees of the crystallinity of the SiGe crystal layer 305 deposited on the Si crystal layer 304 is not observed.

As should be appreciated from the foregoing, when the Si substrate is left in vacuum after the thermal cleaning, the substrate surface is contaminated, whereas when the Si crystal layer having a relatively small film thickness is deposited on the Si substrate which is then left in vacuum, the substrate surface is not contaminated, and the satisfactory SiGe crystal layer is formed. The reason for this will now be described.

Since the substrate just after the thermal cleaning is exposed to a high temperature and vacuum atmosphere, it is considered that the substrate is rough in an atomic level. As a matter of course, it is considered that, under the condition, atoms residing on an uppermost surface of the substrate surface has dangling bonds, and are relatively active. Upon oxygen molecules or the like reaching the substrate surface in such a state (air resides even in ultra-high vacuum atmosphere), the oxygen molecules or the like easily bond to the atoms on the substrate surface. This is considered to be a main cause of contamination of the crystal surface due to impurities. That is, the substrate surface just after the thermal cleaning tends to be contaminated by the impurities. For this reason, when the substrate is left in vacuum for 900 seconds and then the SiGe crystal is grown on the substrate, the degrees of flatness and crystallinity of the SiGe crystal is degraded.

On the other hand, as described above, when the Si crystal layer having a relatively small film thickness is grown on the substrate under the condition in which the substrate surface is not contaminated so much, after the thermal cleaning, it is considered that the substrate surface roughened by the thermal cleaning is restored to some degrees (hereinafter, the Si crystal layer having the relatively small film thickness is referred to as a surface-restoring layer). Probably, the number of dangling bonds that actively react with a gas such as oxygen is reduced. Therefore, even if the substrate having the restored surface is left for a long time (here, 900 seconds), the substrate is kept to be relatively clean.

As should be appreciated, basically, the surface-restoring layer used in the present invention and the conventional Si buffer layer play different roles. Specifically, the conventional buffer layer serves to cover the contaminations of the surface, and it is therefore necessary to deposit the Si buffer layer to have a relatively large thickness (generally, several tens nm or more). On the other hand, the surface-restoring layer of the present invention serves to restore the surface of the Si substrate which has been roughened by the thermal cleaning and form the substrate surface resistive to contamination. Since the roughness of the substrate surface caused by the thermal cleaning is considered to be several-atom layer order, such roughness can be restored by depositing a very thin Si crystal layer (approximately 0.5 nm). That is, the Si crystal layer functions as the surface-restoring layer. In order for the Si crystal layer to function as the surface-restoring layer, the film thickness of approximately 1 nm is sufficient. So, the Si crystal layer having a film thickness of not less than one monolayer and not more than 1 nm is grown on the Si substrate after the thermal cleaning.

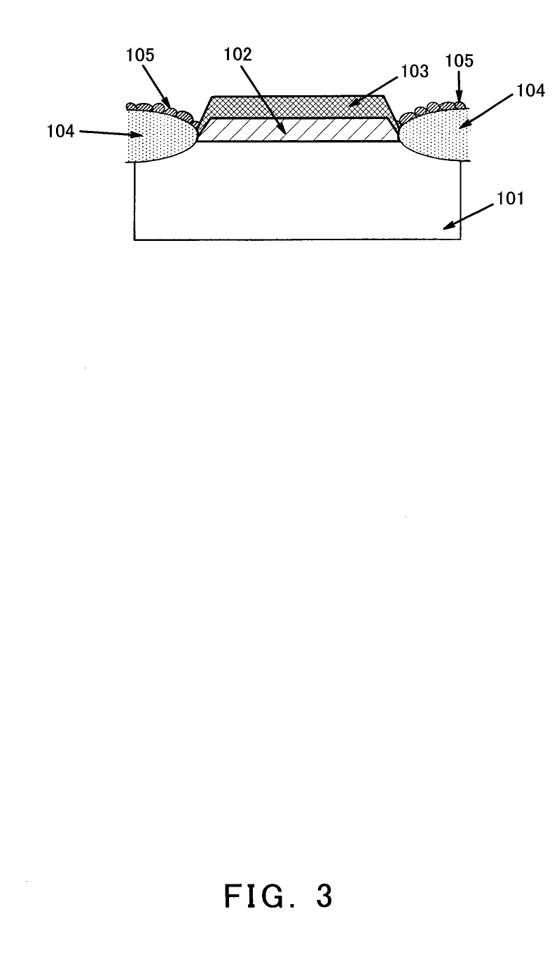

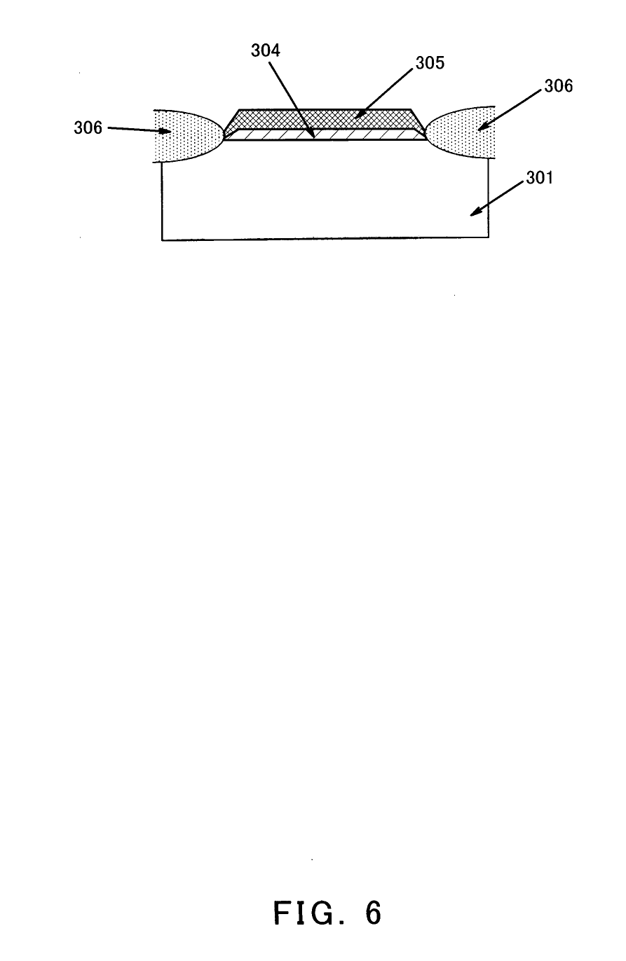

In the conventional method, since the Si buffer layer having a relatively large thickness, for example, of several tens nm or more, is grown as described above, longer growth time is necessary as compared to the case where the Si crystal layer having a relatively small thickness, for example, of approximately 0.5 nm (approximately 1 nm at maximum) is grown as in this embodiment. As a result, as described with reference to FIG. 3, polycrystal 105 is unfavorably deposited on the SiO₂ film when the selective epitaxial growth is performed. On the other hand, in this embodiment, growth time shorter than that in the conventional method, is sufficient. For this reason, as shown in FIG. 6, even when the Si substrate 301 is patterned with the SiO₂ film 306 and the Si crystal layer (surface-restoring layer) 304 and the SiGe crystal layer 305 are selectively epitaxially grown, polycrystal is not deposited on the SiO₂ film 306. Consequently, in this embodiment, superior selectivity is achieved.

In this embodiment, it is important that the Si crystal layer 304 corresponding to the surface-restoring layer be deposited at a temperature (600° C.) between the substrate temperature of the Si substrate 301 at which thermal cleaning is performed (here, 850° C.) and the growth temperature at which crystal growth of the SiGe crystal layer 305 is performed (here, 500° C.). Since an apparatus configured to heat the substrate using the infrared lamp is used as the crystal growth apparatus in this embodiment, the substrate temperature is increased and reduced quickly and in a short time (For example, the substrate temperature can be reduced from 850° C. to 500° C. in approximately 30 seconds). However, in an apparatus configured to heat the substrate using a heater, longer time is required to increase and reduce the substrate temperature. In particular, longer time is required for larger change in the substrate temperature. In such an apparatus, time required for reducing the temperature from 850° C. to approximately 600° C. is shorter than the time required for reducing the temperature from 850° C. to 500° C. In this embodiment, since it is necessary to form the surface-restoring layer before the surface of the substrate is fully contaminated, it is necessary to minimize the time that lapses from when the thermal cleaning is completed until when the surface-restoring layer is formed. Accordingly, preferably, the Si crystal layer 304 serving as the surface-restoring layer is deposited at a temperature between the temperature of the thermal cleaning and the temperature at which the crystal growth of the SiGe crystal layer 305 is performed.

As described above, in the crystal growth apparatus using the heater, rapid increase and decrease in the temperature is not achieved unlike in the crystal growth apparatus using the infrared lamp, and, therefore, longer time is required to increase and reduce the temperature than in the crystal growth apparatus using the infrared lamp. For this reason, in the conventional forming method, in the case of using the crystal growth apparatus using the heater, the substrate surface is greatly contaminated. Therefore, the method of forming the semiconductor crystal of the present invention which is adapted to form the surface-restoring layer on the substrate, is considered to be effective in the apparatus using the heater.

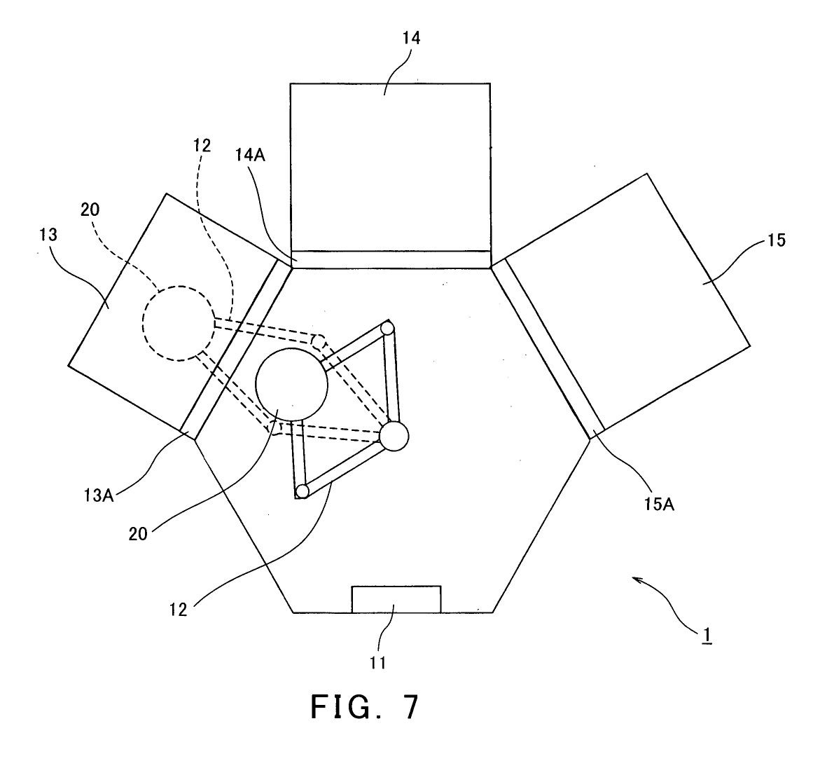

In addition, the forming method of the present invention is effective in a crystal growth apparatus in which the substrate needs to be carried to a predetermined position after the thermal cleaning. FIG. 7 shows an example of a configuration of such an apparatus. FIG. 7 is a plan view schematically showing a configuration of the crystal growth apparatus having a plurality of chambers. As shown in FIG. 7, a crystal growth apparatus 1 comprises a wafer inlet/outlet 11 through which a wafer (Si substrate) 20 is carried in or carried out, a chamber 13 exclusively for thermal cleaning where thermal cleaning is performed, a first crystal growth chamber 14, and a second crystal growth chamber 15. The chamber 13 exclusively for thermal cleaning, the first crystal growth chamber 14 and the second crystal growth chamber 15 are provided with shutters 13A, 14A, and 15A, respectively. The crystal growth apparatus 1 has a carrier 12 for carrying the wafer 20 between the wafer inlet/outlet 11 and each of the chambers, or between the chambers.

An operation of the crystal growth apparatus 1 configured as described above will now be described. First, the wafer 20 is carried into the crystal growth apparatus 1 through the wafer inlet/outlet 11. The carrier 12 carries the wafer 20 so carried into the crystal growth apparatus 1 to a point before the shutter 13A of the chamber 13 exclusively for thermal cleaning. Here, when the shutter 13A opens, the carrier 12 carries the wafer 20 into the chamber 13 exclusively for thermal cleaning (see broken lines). Thereafter, the shutter 13A closes and the wafer 20 is thermally cleaned inside the chamber 13 exclusively for thermal cleaning.

Subsequently, crystal growth is performed on the wafer 20 that has gone through the thermal cleaning as described above. To this end, after the shutter 13A of the chamber 13 exclusively for thermal cleaning opens, the carrier 12 takes out the wafer 20 from the inside of the chamber 13 exclusively for thermal cleaning. Then, the carrier 12 carries the wafer 20 taken out from the inside of the chamber 13 exclusively for thermal cleaning to a point before the shutter 14A of the first crystal growth chamber 14. Thereafter, as in the case of the thermal cleaning, the carrier 12 carries the wafer 20 into the first crystal growth chamber 14 after the shutter 14A opens. Thereafter, the shutter 14A closes and the crystal growth of the Si crystal layer 304 is performed inside the first crystal growth chamber 14.

After the crystal growth is finished inside the first crystal growth chamber 14, crystal growth of semiconductor crystal is further performed. To this end, after the shutter 14A of the first crystal growth chamber 14 opens, the carrier 12 takes out the wafer 20 from the inside of the first crystal growth chamber 14. Then, the carrier 12 carries the wafer 20 to a point before the shutter 15A of the second crystal growth chamber 15 in the same manner as described above, and after the shutter 15A opens, the carrier 12 carries the wafer 20 into the second crystal growth chamber 15. Then, the shutter 15A closes and the crystal growth of the SiGe crystal layer 305 is performed inside the second crystal growth chamber 15.

Thus, when the carrier 12 carries the wafer 20 from the chamber 13 exclusively for thermal cleaning into the first crystal growth chamber 14 and from the first crystal growth chamber 14 into the second crystal growth chamber 15, a certain time is required. Since the time required for carrying the wafer 20 corresponds to the time during which the wafer 20 is left in vacuum, the surface of the wafer 20 cleaned by the thermal cleaning is contaminated.

In the case of the crystal growth apparatus 1, time during which the substrate is left in vacuum becomes longer than in the crystal growth apparatus in which thermal cleaning and crystal growth are performed inside the same chamber. Therefore, by using the forming method of this embodiment, it is possible to form semiconductor crystal with quality higher than that of the semiconductor crystal formed by the conventional forming method.

It should be noted that a hydrogen gas is not always necessary during thermal cleaning but only heating the substrate in ultra-high vacuum is satisfactory. In addition, the gases used here are not limited to the Si₂H₆ gas and GeH₄ gas, but a SiH₃CH₃ gas or the like may be added to cause SiGeC or SiC crystal to be deposited on the Si substrate. The composition of these crystals may be inconstant and gradationally changeable in the thickness direction thereof The pressures of the gases, and the growth temperature and growth time of crystal, are not limited to the above-mentioned example. Further, the crystal growth method is not limited to the UHV-CVD process, but other methods including a CVD process such as LP-CVD process, molecule beam evaporation (MBE), etc, may be employed.

### Second Embodiment

In a second embodiment, a description will be given of a method of forming semiconductor crystal, which is capable of depositing satisfactory SiGe on a Si substrate without the Si crystal layer which is left in vacuum for a relatively long time.

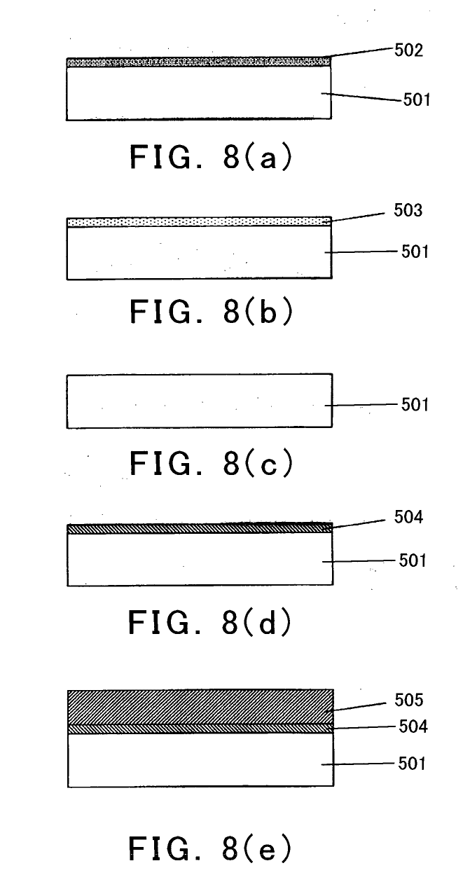

FIGS. 8(a) to 8(e) are views for explaining steps of a method of forming semiconductor crystal according to a second embodiment of the present invention and cross-sectional views of products formed in the steps. As shown in FIG. 8(a), on a Si substrate 501, a native oxide film 502 exists. The Si substrate 501 provided with the native oxide film 502 on the surface thereof is cleaned using a mixed solution containing sulfuric acid and hydrogen peroxide solution, thereby removing organic substances and metal contamination substances on the substrate surface. Then, the Si substrate 501 is cleaned using an aqueous solution containing ammonia and hydrogen peroxide, thereby removing small particles adhering to the Si substrate 501. Further, using a hydrofluoric acid solution, the native oxide film 502 on the surface of the Si substrate 501 is removed. Then, the Si substrate 501 is re-immersed in the aqueous solution containing ammonia and hydrogen peroxide, thereby forming a thin protection oxide film 503 on the surface of the Si substrate 501 as shown in FIG. 8(b).

The Si substrate 501 that has gone through the above pretreatment is introduced into the crystal growth apparatus. In this embodiment, as in the first embodiment, an example using the ultra-high vacuum chemical vapor deposition process (UHV-CVD process), will be described as the crystal growth method. In this embodiment, first, the Si substrate 501 is introduced into the crystal growth chamber, which is then evacuated to 266.644×10⁻⁹ Pa. Then, the Si substrate 501 is heated up to a temperature of a temperature of 850° C. in a hydrogen gas atmosphere to cause the protection oxide film 503 formed on the Si substrate 501 to be removed by sublimation and contaminations on the surface of the Si substrate 501 to be removed, thereby exposing a clean surface of the Si substrate 501 as shown in FIG. 8(c).

Then, the temperature of the Si substrate 501 is reduced for 30 seconds to 600° C. and temporarily kept at 600° C. Then, the Si₂H₆ gas and the GeH₄ gas are fed into the crystal growth chamber so that the pressure of the Si₂H₆ gas and the pressure of the GeH₄ gas are 933.254×10⁻⁵ Pa and 333.305×10⁻⁴ Pa, respectively inside thereof, thereby causing a first SiGe crystal layer 504 to be epitaxially grown on the Si substrate 501, as shown in FIG. 8(d). The growth time is set to 30 seconds. Thereby, the first SiGe crystal layer 504 is grown to be approximately 10 nm at a Ge concentration of 26%. Then, the substrate temperature is reduced to 500° C. which is a growth temperature of the SiGe crystal to be obtained, in which state, the Si substrate 501 is left for 15 minutes (900 seconds). Thereafter, as shown in FIG. 8(e), a second SiGe crystal layer 505 is deposited on the first SiGe crystal layer 504. At this time, the Si₂H₆ gas and the GeH₄ gas are fed into the crystal growth chamber so that the pressure of the Si₂H₆ gas and the pressure of the GeH₄ gas are 933.254×10⁻⁵ Pa and 333.305×10⁻⁴ Pa, respectively. The growth time is set to 580 seconds. Under the condition, the second SiGe crystal layer 505 is grown to be 130 nm at a Ge concentration of 26%.

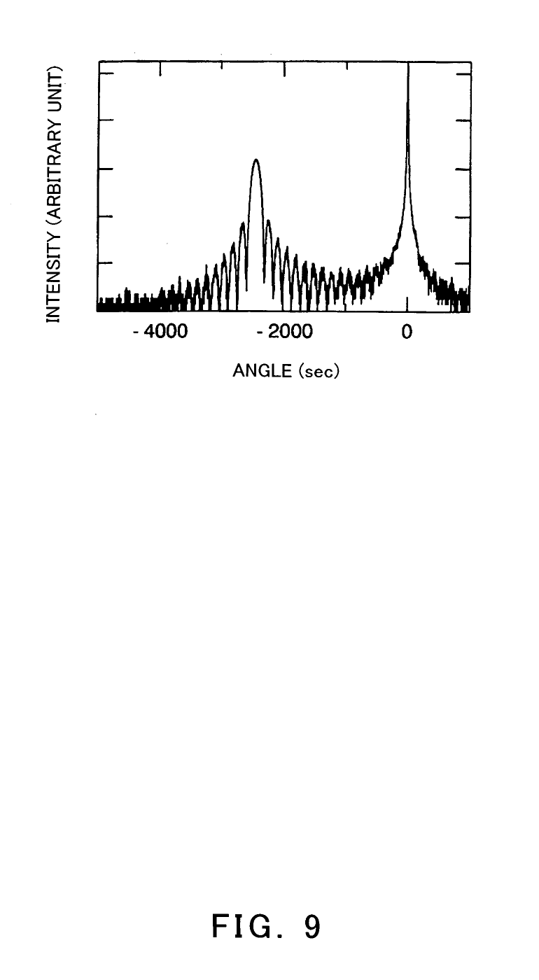

FIG. 9 shows a XRD spectrum of the SiGe crystal layer (the first SiGe crystal layer 504 and the second SiGe crystal layer 505 in FIG. 8) formed as described above. In FIG. 9, as in the case of FIGS. 1 and 2, a sharp peak appearing at a location of “0 sec” is a peak due to diffraction of (004) planes of Si used as the substrate and a peak appearing in the vicinity of 2200 sec is a peak due to diffraction of the first SiGe crystal layer 504 and the second SiGe crystal layer 505. Periodic fine peaks appearing around the main peak in the vicinity of 2200 sec are fringes that exhibit the degrees of flatness and crystallinity of the first SiGe crystal layer 504 and the second SiGe crystal layer 505. With reference to FIG. 9, the fringes are very clear, which shows that the degrees of crystallinity and flatness of the deposited first SiGe crystal layer 504 and second SiGe crystal layer 505 are very high.

As can be seen from the spectrum shown on the uppermost side in FIG. 1, the fringes almost vanish and degrees of flatness and crystallinity of the SiGe crystal layer are degraded, when the Si substrate is left in vacuum for 900 seconds and then the SiGe crystal layer is deposited to be 130 nm at the Ge concentration of 26% on the Si substrate without depositing the first SiGe crystal layer 504 shown in FIG. 8 on the Si substrate after the thermal cleaning. Thus, the SiGe crystal layer formed without depositing the first SiGe crystal layer 504 is identical in structure to the first SiGe crystal layer 504 and the second SiGe crystal layer 505 formed in the forming method of this embodiment. Likewise, in forming the crystals, the substrate is left in vacuum for 900 seconds. Nonetheless, by growing the SiGe crystal layer twice after the thermal cleaning as in this embodiment, the degrees of crystallinity and flatness of the finally obtained SiGe crystal layer is greatly improved.

Subsequently, a description will be given of the reason why the SiGe crystal layer deposited on the Si substrate left in vacuum for a relatively long time can keep high degrees of crystallinity and flatness by growing the SiGe crystal layer twice.

The SiGe crystal layer keeps high degrees of crystallinity and flatness for the same reason as described in the first embodiment. Specifically, the substrate just after the thermal cleaning is rough and very active in atomic level. The substrate surface in such an active condition is easily contaminated by air (in particular oxygen) remaining in ultra-high vacuum. But, by growing SiGe within a relatively short time (before contamination progresses so much) after the thermal cleaning, the substrate surface roughened by the thermal cleaning is somewhat restored. That is, in this embodiment, the first SiGe crystal layer 504 shown in FIG. 8 functions as a surface-restoring layer.

In this embodiment, it is important that the first SiGe crystal layer 504 as the surface-restoring layer be deposited at a temperature (600° C.) between the substrate temperature (here, 850° C.) of the Si substrate 501 at which the thermal cleaning is performed and the growth temperature (here, 500° C.) at which crystal growth of the second SiGe crystal layer 505 is performed. In this embodiment, since the crystal growth apparatus that heats the substrate using the infrared lamp is used, the substrate temperature is quickly increased and reduced in a very short time (For example, the substrate temperature is reduced from 850° C. to 500° C. in about 30 seconds). But, in the case of using the apparatus that heats the substrate using the heater, longer time is required to cause the substrate temperature to be increased and reduced. Longer time is required for larger change in the temperature. In such an apparatus, time required for reducing the temperature from 850° C. to 600° C. is shorter than time required for reducing the temperature from 850° C. to 500° C. In this embodiment, it is necessary to form the surface-restoring layer 504 before the surface of the substrate is fully contaminated, and it is therefore necessary to minimize the time that lapses from when the thermal cleaning is completed until the surface-restoring layer 504 is formed. Accordingly, preferably, the first SiGe crystal layer 504 serving as the surface-restoring layer is deposited at a temperature between the temperature of the thermal cleaning and the temperature at which the crystal growth of the second SiGe crystal layer 505 is performed.

It is also important that the film thickness of the first SiGe crystal layer 504 be thin. But, if the SiGe crystal layer is deposited to be 130 nm at a Ge concentration of about 27% at approximately 600° C., then defects tend to occur due to large distortion of the SiGe crystal layer. But, under the low temperature of approximately 500° C., defects are less likely to occur. For such reason, the first SiGe crystal layer 504 that is thin is deposited on the Si substrate 501 to restore the surface of the Si substrate 501, and thereafter, the substrate temperature is reduced to the temperature at which crystal growth of the second SiGe crystal layer 505 is performed (here, 500° C.), and under the temperature, the second SiGe crystal layer 505 is deposited.

In this embodiment, a description has been made of the growth of SiGe on the Si substrate. Alternatively, the method may be used in formation of SiGeC or SiC crystal on the Si substrate. In addition, the growth temperature is not intended to be limited to the above-mentioned example. Specifically, crystal growth may be performed at a temperature (intermediate temperature) lower than the temperature at which the thermal cleaning is performed and higher than the temperature at which the crystal growth is mainly performed. Such temporal crystal growth at the intermediate temperature may be performed once or more. Therefore, in an apparatus that requires considerable time to reduce the substrate temperature, the temporal crystal growth at the intermediate temperature may be performed plural times. The kind or pressure of the source gases for use in the crystal growth are not limited to the above. As the crystal growth method, CVD process such as LP-CPD process, MBE process or the like may be used, in addition to the UHV-CVD process. That is, the present invention is effective in the crystal growth method in which the thermal cleaning is performed at a temperature higher than the temperature of crystal growth before the crystal growth.

Hereinbelow, a description will be given of how soon the crystal layer such as the SiGe crystal layer (Si crystal layer 304 in FIG. 4) in the first embodiment or the temporal SiGe crystal layer in the second embodiment (first SiGe crystal layer 504 in FIG. 8) that function as the surface-restoring layer, should be formed, after the thermal cleaning. As shown in FIG. 1, under the experimental condition (degree of vacuum of the crystal growth chamber where the substrate is left is 666.61×10⁻⁹ Pa), severe damage is not generated in the SiGe crystal deposited on the substrate left at least for 600 seconds. Nonetheless, as described above, the main cause of contamination occurring in the case where the Si substrate is left in vacuum is caused by the air remaining inside the crystal growth apparatus. So, contamination does not progress so fast if the substrate is left for a long time under the condition of high degree of vacuum inside the crystal growth chamber, but progresses fast under the condition of low degree of vacuum inside the crystal growth chamber. Therefore, allowable time during which the substrate can be left (hereinafter allowable time) is determined by the degree of vacuum inside the crystal growth apparatus. Furthermore, strictly speaking, probability of adhesion of the remaining air onto the substrate varies depending on the substrate temperature. Here, as a rough standard, the allowable time is determined under the condition in which a product of the time during which the substrate is left and the degree of vacuum inside the crystal growth apparatus is equal to a value or less. Specifically, with reference to the result in FIG. 1, the contamination of the surface of the substrate does not progress so much when the substrate is left for 600 seconds under the degree of vacuum of 666.61×10⁻⁹ Pa. Therefore, the surface-restoring layer should be deposited on the substrate within time determined under the condition in which the product of the time and degree of vacuum is equal to 399966×10⁻⁹ (sec Pa) or less.

### Embodiment 3

A higher-performance semiconductor device can be fabricated using the semiconductor crystal formed in the above-mentioned forming method. Here, in a third embodiment, the fabrication method of the semiconductor device will be described.

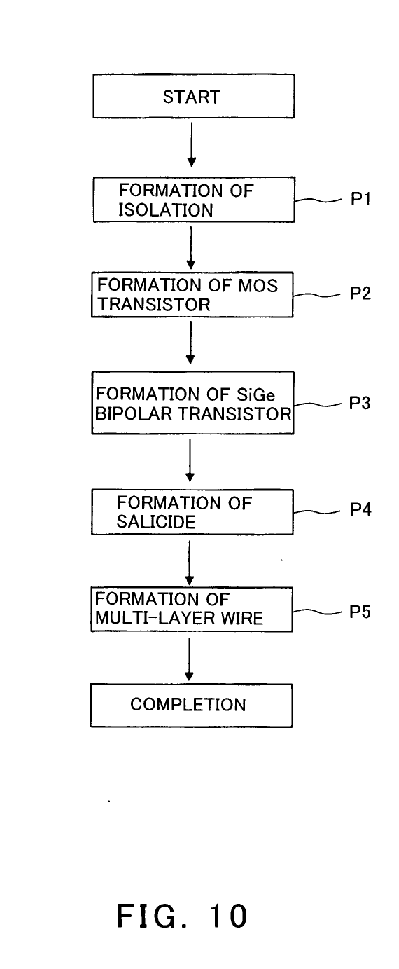

The fabrication method of the semiconductor device is described in detail in, for example, Japanese Laid-Open Patent Application Publication No. 2000-332025. This method is, as shown in FIG. 10, comprised of blocks of steps: (A) formation of isolation, (B) formation of a MOS transistor, (C) formation of a SiGe bipolar transistor, (D) formation of salicide, and (E) formation of a multi-layer wire.

In the step of (C) formation of the SiGe bipolar transistor among these steps, SiGe crystal forming a base layer of the SiGe hetero bipolar transistor is formed according to the forming method of the semiconductor crystal forming the surface-restoring layer described in the above embodiment. Thereby, the SiGe bipolar transistor that contains crystal defects less than that of the conventional transistor can be formed. Since the crystal defects in the base layer can be thus reduced, it is possible to achieve the SiGe hetero bipolar transistor that has a satisfactory electric characteristic in which a leak current is less than that of the conventional transistor. In particular, the forming method of the present invention is preferably used in selective growth of SiGe, because density of crystal defects is reduced.

Further, an integrated circuit comprising a plurality of SiGe hetero bipolar transistors can achieve improved yield and a reduced cost, because of a reduced variation in transistor properties. Because of the reduced variation in the properties, performance of a circuit provided with a pair of transistors having similar properties (balance-type circuit, for example, double-balanced mixer, or the like) is improved.

In addition to SiGe, the present invention is applicable to bipolar transistors that comprise SiGeC or SiC in base regions.

Moreover, in addition to the bipolar transistor, the present invention is applicable to devices that comprise SiGe, SiGeC or SiC in channel regions of electric field transistors.

Numerous modifications and alternative embodiments of the invention will be apparent to those skilled in the art in view of the foregoing description. Accordingly, the description is to be construed as illustrative only, and is provided for the purpose of teaching those skilled in the art the best mode of carrying out the invention. The details of the structure and/or function may be varied substantially without departing from the spirit of the invention and all modifications which come within the scope of the appended claims are reserved.

1. A method of growing semiconductor crystal, comprising:
a first step of heating a Si substrate to clean a surface of the Si substrate;
a second step of epitaxially growing first semiconductor crystal containing at least Si on the Si substrate so as to contact the surface of the Si substrate by feeding a first gas containing at least Si to the Si substrate; and
a third step of epitaxially growing second semiconductor crystal on the first semiconductor crystal so as to contact a surface of the first semiconductor crystal by feeding a second gas to the surface of the first semiconductor crystal, wherein
the second semiconductor crystal comprises a material different from Si,
a growth temperature of the first semiconductor crystal in the second step is lower than a substrate temperature of the Si substrate in the first step and is higher than a growth temperature of the second semiconductor crystal in the third step, and
the first semiconductor crystal has a film thickness of not less than 1 monolayer and not more than 1 nm, the method further comprising:
stopping feeding the first gas for a predetermined time period between the second and third steps.

2. (canceled)

3. The method of forming semiconductor crystal according to claim 1, wherein the first semiconductor crystal is Si.

4. The method of forming semiconductor crystal according to claim 1, wherein the second semiconductor crystal contains Si and Ge.

5. The method of forming semiconductor crystal according to claim 4, wherein the second semiconductor crystal further contains C.

6. The method of forming semiconductor crystal according to claim 1, wherein the second semiconductor crystal contains Si and C.

7. The method of forming semiconductor crystal according to claim 1, wherein the first semiconductor crystal contains Ge, and both the second semiconductor crystal and the first semiconductor crystal are made of an identical material.

8. The method of forming semiconductor crystal according to claim 7, wherein the first semiconductor crystal further contains C.

9. The method of forming semiconductor crystal according to claim 1, wherein the first semiconductor crystal contains C, and both the second semiconductor crystal and the first semiconductor crystal are made of an identical material.

10-18. (canceled)
